(19) United States
(12) Patent Application Publication
(10) Pub. No.: US 2013/0075151 A1
(43) Pub. Date: Mar. 28, 2013

(54) ELECTRO-MAGNETIC WAVE FILTERING AND IMPEDING BOARDS

(71) Applicants: Po-Ming CHEN, Tainan (TW); Shih-Ming Lu, Tainan (TW)

(72) Inventors: Po-Ming CHEN, Tainan (TW); Shih-Ming Lu, Tainan (TW)

(21) Appl. No.: 13/243,374

(22) Filed: Sep. 23, 2011

(51) Int. Cl. H05K 9/00

(52) U.S. Cl. 174/390

(57) ABSTRACT

An electro-magnetic wave filtering and impeding board is made of metal and includes a first side and a second side. The first side has multiple linear slots and the second side includes multiple concaved geometric holes which communicate with the linear slots. The electro-magnetic waves are impeded by the metallic material and weakened when passing through the linear slots and the geometric holes so as to impede the electro-magnetic waves.

### FIELD OF THE INVENTION

The present invention relates to an electro-magnetic wave filtering and impeding board, and more particularly, to a metallic board with linear slots and geometric holes which communicate with the linear slots.

### BACKGROUND OF THE INVENTION

It is confirmed that if the human cells are exposed under high density of electro-magnetic waves will cause lesion which generally means cancers. There are reports issued that residents have higher possibility to get cancers when compared with those live at a distance from the communication signals emitting bases and high-voltage electric transformer boxes. Accordingly, how to impede the electro-magnetic waves around the living area becomes an important concern.

Taiwan Patent No. 592035 discloses an “electro-magnetic wave impeding structure and the method for making the same”, and comprises transparent boards and netted films, wherein the transparent boards each have a first side and a second side, and each of the netted films has a first side and a second side. The second side of the netted film is connected to the first side of the transparent board. The first side of the netted film includes a layer of pressure-sensitive glue which replaces the UV transparent glue.

Taiwan Patent No. 531586 discloses an “electro-magnetic wave impeding construction parts and the method for making the same”, and comprises a board having one portion which is made by mixture of electric-conductive material and the main contents of the board. An electro-magnetic waves impeding film made by printed electric-conductive oil is connected to the portion.

These two references disclose a complicated structure with high manufacturing cost. When they are applied to a construction member with large area, the price will be increased significantly.

The present invention intends to provide an electro-magnetic filtering and impeding board which is less expensive and can effectively filter and impede weak electro-magnetic waves so that the present invention can be applied to the construction member of large area.

### SUMMARY OF THE INVENTION

The present invention relates to an electro-magnetic wave filtering and impeding board is made of metal and comprises a first side and a second side, wherein the first side has multiple linear slots and the second side of the board has concaved geometric holes which communicate with the linear slots. The minimum width of the geometric holes is smaller than the perpendicular distance between the first and second sides of the board.

Preferably, the linear slots are tapered in a direction perpendicular to the first side of the board and parallel to the first side.

Preferably, the geometric holes communicate with bottoms of each of the linear slots, and the width of the geometric holes in the direction parallel to the linear slots is wider than the width of the geometric holes in the direction perpendicular to the linear slots.

Preferably, the geometric holes are polygonal holes and tapered in the direction perpendicular to the second side of the board. Preferably, the geometric holes are triangular holes. The geometric holes are arranged in multiple rows and located corresponding to the linear slots. The polygonal holes in any row are evenly spaced. The polygonal holes in any of the adjacent rows are located alternatively to each other. An offset distance between adjacent polygonal holes along the direction of the linear slots is smaller than a gap between any adjacent polygonal holes in each row. The gap is half of the distance of any adjacent polygonal holes in each row.

Preferably, the linear slots are tapered in the direction perpendicular to the first side of the board and are arranged in multiple rows which intersect perpendicularly at even distance to each other on the first side. Multiple square pyramids are formed between the linear slots and located as a matrix pattern. The geometric holes communicate with intersections of the linear slots and are polygonal-cone shaped holes, preferably, are triangular-cone shaped holes.

Preferably, the number of the geometric holes in the board 1 is between 8000 to 450000 per meter square, preferably, is between 250000 to 400000 per meter square.

Preferably, the HBR of the board is between 10 to 90 and ductility of the board is between 4 to 45.

When the electro-magnetic waves pass through the board, the waves are weakened due to multiple times of small scales of reflections between the linear slots and the geometric holes. Besides, the metallic board is a superior electro-magnetic waves impeding material which reduces the energy of the electro-magnetic waves.

Besides, the boards are good for absorbing sound so that the boards of the present invention reduce noise and electro-magnetic waves.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 is a perspective view to show the board of the present invention;

FIG. 2 shows the geometric holes in the second side of the board of the present invention;

FIG. 3 shows the second side of the real product of the board of the present invention;

FIG. 4 shows the first side of the real product of the board of the present invention;

FIG. 5 shows the first side of the second embodiment of the board of the present invention;

FIG. 6 shows the second side of the second embodiment of the board of the present invention, and

FIG. 7 is a cross sectional view of the second embodiment of the board of the present invention.

### DETAILED DESCRIPTION OF THE PREFERRED EMBODIMENT

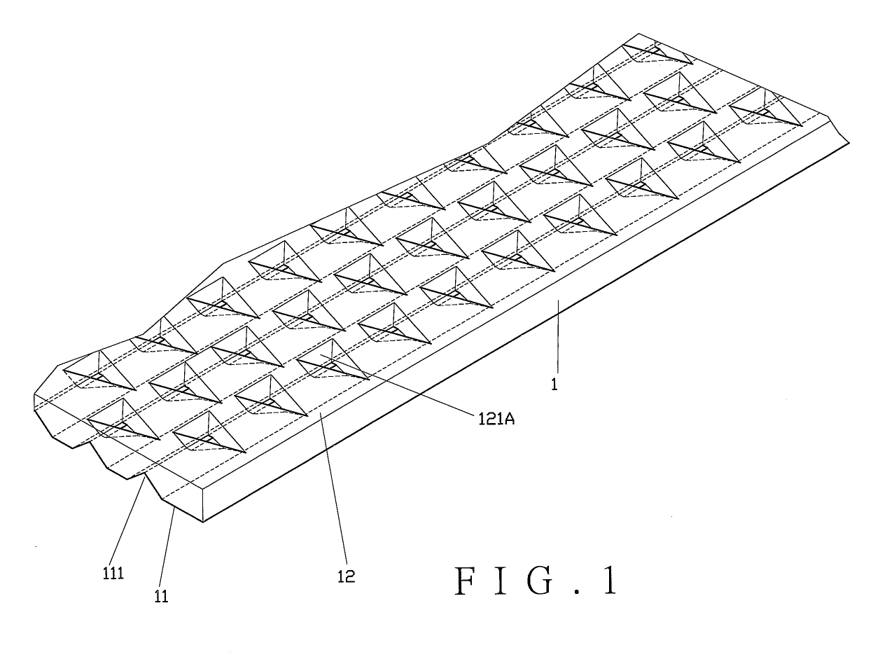

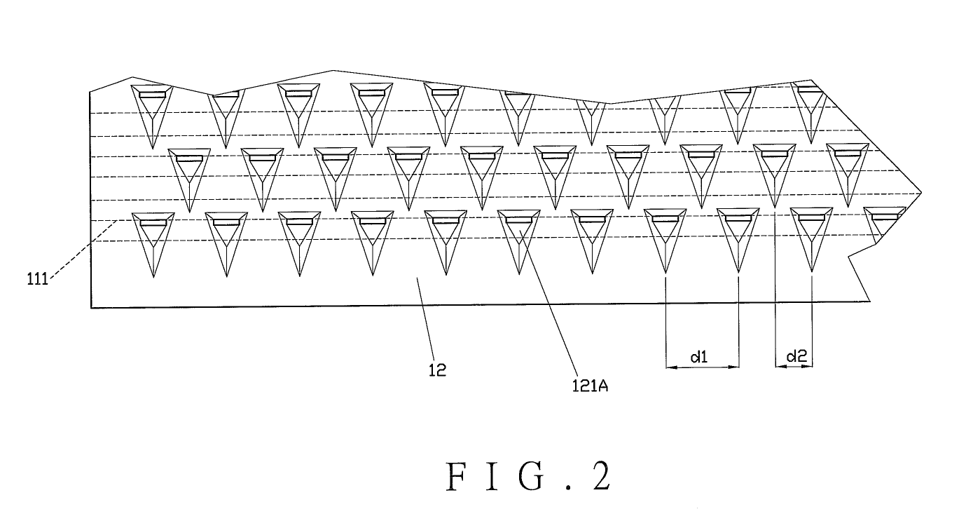

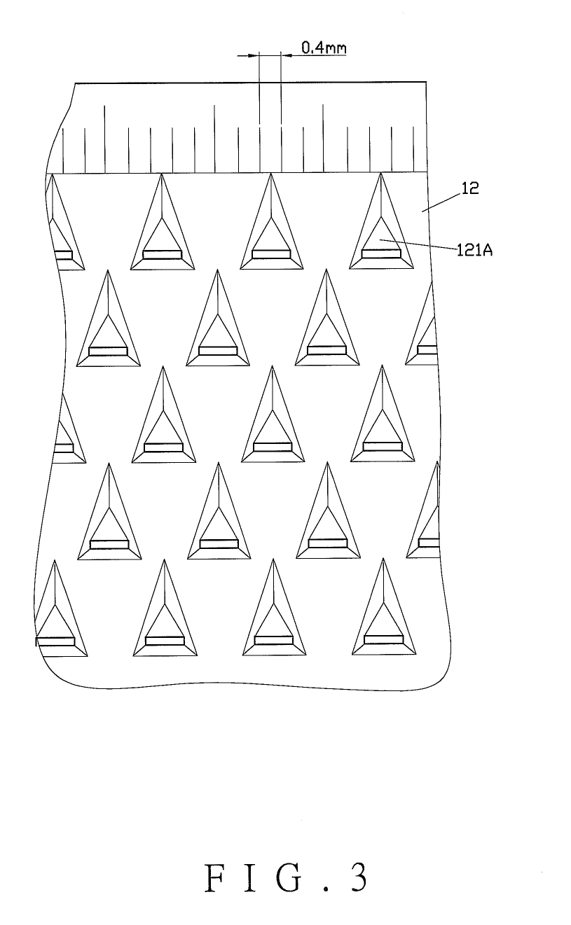

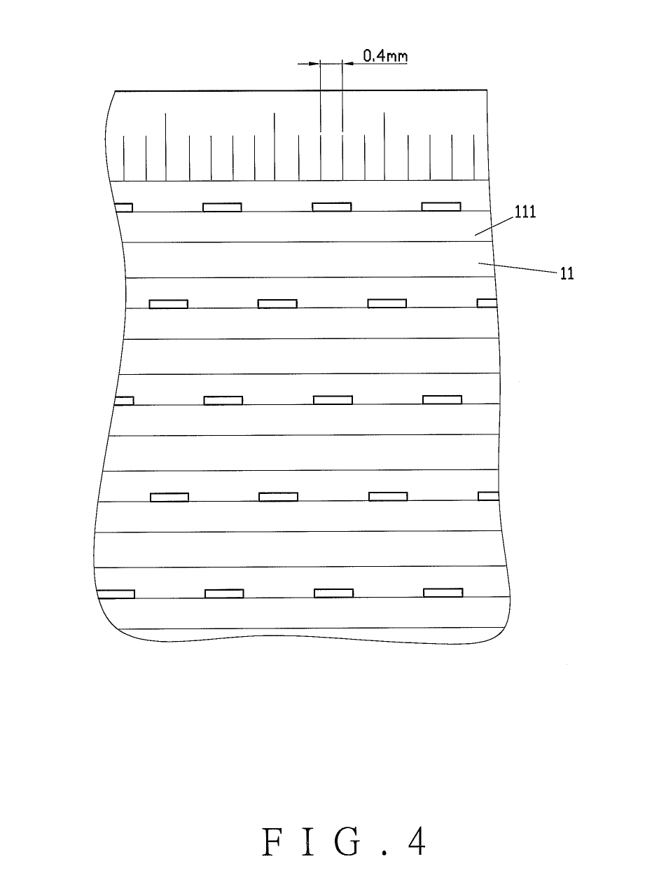

Referring to FIGS. 1 to 4, the electro-magnetic wave filtering and impeding board comprises a board 1 which has a first side 11 and a second side 12. The first side 11 has multiple linear slots 111 which are tapered in the direction perpendicular to the first side 11 of the board 1 and parallel to the first side 11. The second side 12 of the board 1 has concaved geometric holes which are triangular holes 121A and communicate with the linear slots 111. The triangular holes 121A in any of the rows are located evenly separated at a gap d1. The triangular holes 121A in adjacent rows are located alternatively to each other. The triangular holes 121A in any of the adjacent rows are located alternatively to each other. An offset distance d2 between adjacent triangular holes 121A along the direction of the linear slots 111 is smaller than a gap d1 between any adjacent triangular holes 121A in each row. The offset distance d2 is half of the gap d1 of any adjacent polygonal holes in each row. The triangular holes 121A tapered in the direction perpendicular to the second side 12 of the board 1 and communicate with the bottoms of the linear slots 111 in the first side 11. The minimum width of the triangular holes 121A is smaller than the perpendicular distance between the first and second sides 11, 12 of the board 1. In this embodiment, the width of the triangular holes 121A in the direction parallel to the linear slots 111 is wider than the width of the triangular holes 121A in the direction perpendicular to the linear slots 111.

The number of the geometric holes in the board 1 is between 8000 to 450000 per meter square, preferably, between 250000 to 400000 per meter square. The HBR of the board 1 is between 10 to 90 and ductility of the board 1 is between 4 to 45.

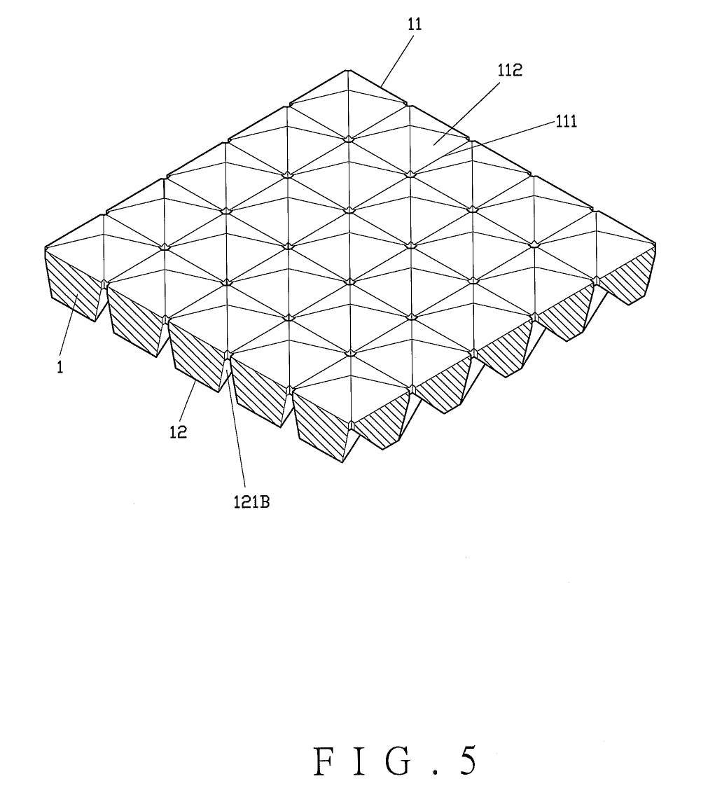

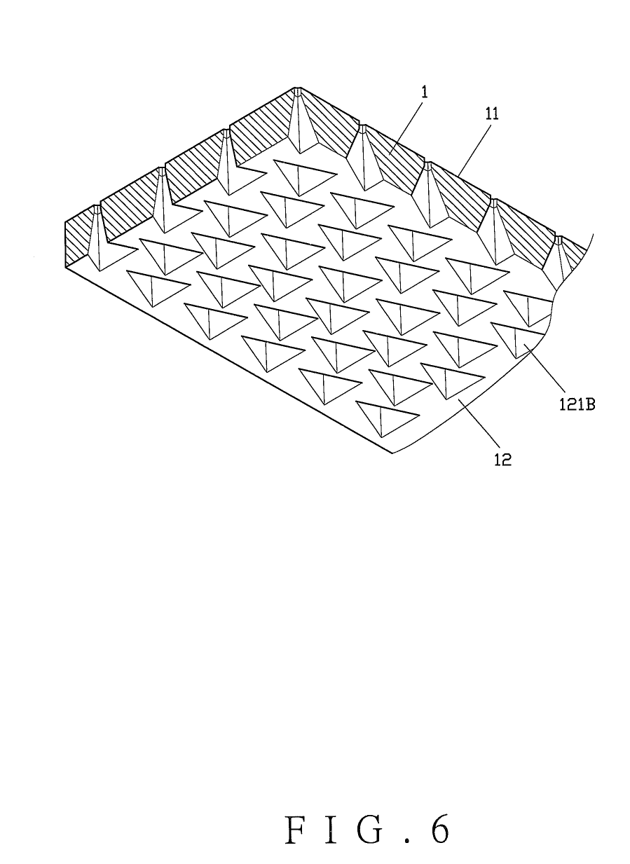

FIGS. 5 to 7 show the second embodiment of the present invention, wherein the differences from the first embodiment are that the linear slots 111 are tapered in the direction perpendicular to the first side 11 of the board 1 and are arranged in multiple rows which intersect perpendicularly at even distance to each other on the first side 11 of the board 1. Multiple square pyramids 112 are formed between the linear slots 111 and located as a matrix pattern. The geometric holes are triangular-cone holes 121B and communicate with intersections of the linear slots 111.

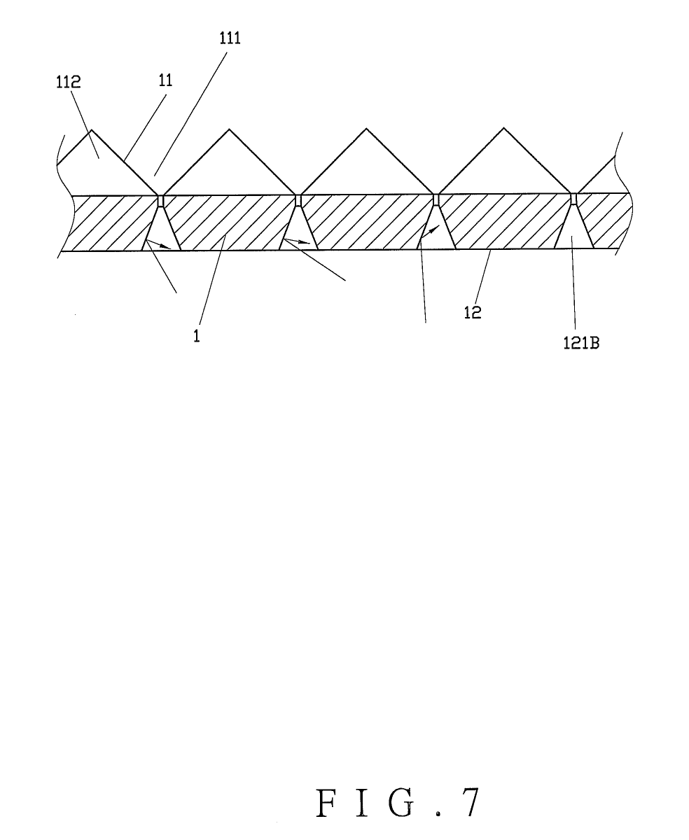

As shown in FIG. 7, when the electro-magnetic waves pass through the second embodiment of the board 1, regardless passing from the first side 11 or the second side 12, the electro-magnetic waves have multiple times of small scale of reflections between the linear slots 111 of the first side 11 and in the interior of the triangular-cone holes 121B of the second side 12 of the board 1 so that the electro-magnetic waves are filtered and weakened. Because the board 1 is made by metal which is superior for impeding the electro-magnetic waves, so that when the electro-magnetic waves pass through the first and second sides 11, 12 of the board 1, the energy of the electro-magnetic waves are filtered and weakened by the surfaces of the square pyramids 112 and the insides of the triangular-cone holes 121B. Furthermore, the metal is a good conductive agent for the electro-magnetic waves, so that the electro-magnetic waves are automatically gathered to the board 1 and weakened by resonance transmission of the atoms of the metal of the board 1.

Referring to charts 1 to 3, the applicant authorizes Industrial Technology Research Institute, Taiwan to conduct a test about filtering and impeding of electro-magnetic waves between the first embodiment of the board of the present invention and the aluminum board.

CHART 1
the electro-magnetic waves enter the second side 12 of the board 1 of the present invention, wherein
the front surface of the porous board is the second side 12 of the board 1 of the present invention.

| | Frequency | | | | | | | | Remarks |
|---|---|---|---|---|---|---|---|---|---|
| Item | 30 MHZ | 100 MHZ | 300 MHZ | 500 MHZ | 900 MHZ | 1.0 GHZ | 1.5 GHZ | 1.8 GZH | (Unit: dB) |
| Porous | 91 | 91.4 | 91 | 89.5 | 85.5 | 83.5 | 84 | 84 | Electro-magnetic |
| board front | | | | | | | | | material |
| surface | | | | | | | | | (impeding) |
| Porous | 8.9 | 8.3 | 8.0 | 7.4 | 6.9 | 6.3 | 6.1 | 5.7 | Electro-magnetic |
| board front | | | | | | | | | material |
| surface | | | | | | | | | (absorbing) |

CHART 2
the electro-magnetic waves enter the first side 11 of the board 1 of the present invention, wherein
the rear surface of the porous board is the first side 11 of the board 1 of the present invention.

| | Frequency | | | | | | | | Remarks |
|---|---|---|---|---|---|---|---|---|---|
| Item | 30 MHZ | 100 MHZ | 300 MHZ | 500 MHZ | 900 MHZ | 1.0 GHZ | 1.5 GHZ | 1.8 GZH | (Unit: dB) |
| Porous | 68.5 | 68.5 | 68.3 | 64.5 | 60 | 60.5 | 60 | 60 | Electro-magnetic |
| board rear | | | | | | | | | material |
| surface | | | | | | | | | (impeding) |
| Porous | 7.3 | 7.0 | 6.7 | 6.4 | 5.9 | 5.4 | 5.1 | 5.0 | Electro-magnetic |
| board rear | | | | | | | | | material |
| surface | | | | | | | | | (absorbing) |

CHART 3
the test report of the electro-magnetic waves passing through the aluminum board.

| | Frequency | | | | | | | | Remarks |
|---|---|---|---|---|---|---|---|---|---|
| Item | 30 MHZ | 100 MHZ | 300 MHZ | 500 MHZ | 900 MHZ | 1.0 GHZ | 1.5 GHZ | 1.8 GZH | (Unit: dB) |
| General | 67.2 | 67 | 67 | 65.5 | 65.4 | 66.7 | 66.4 | 66.5 | Electro-magnetic |
| aluminum | | | | | | | | | material |
| board | | | | | | | | | (impeding) |
| General | 4.3 | 4.0 | 3.8 | 3.5 | 3.1 | 2.7 | 2.3 | 2.1 | Electro-magnetic |
| aluminum | | | | | | | | | material |
| board | | | | | | | | | (absorbing) |

The results listed in the charts 1 to 3 show that the present invention can filter and impede the electro-magnetic waves and reduces the possible injury to people.

While we have shown and described the embodiment in accordance with the present invention, it should be clear to those skilled in the art that further embodiments may be made without departing from the scope of the present invention.

What is claimed is:

1. An electro-magnetic waves filtering and impeding board comprising:
a board having a first side and a second side, the first side having multiple linear slots and the second side of the board having concaved geometric holes which communicate with the linear slots.

2. The board as claimed in claim 1, wherein the linear slots are tapered in a direction perpendicular to the first side of the board and parallel to the first side.

3. The board as claimed in claim 2, wherein the geometric holes communicate with bottoms of the linear slots, a width of the geometric holes in a direction parallel to the linear slots is wider than a width of the geometric holes in a direction perpendicular to the linear slots.

4. The board as claimed in claim 2, wherein the geometric holes are polygonal holes and tapered in a direction perpendicular to the second side of the board, the geometric holes are arranged in multiple rows and located corresponding to the linear slots, the polygonal holes in any row are evenly spaced.

5. The board as claimed in claim 4, wherein the polygonal holes in any of the adjacent rows are located alternatively to each other, an offset distance between adjacent polygonal holes along a direction of the linear slots is smaller than a gap between any adjacent polygonal holes in each row.

6. The board as claimed in claim 5, wherein the offset distance is half of the gap of any adjacent polygonal holes in each row.

7. The board as claimed in claim 6, wherein the polygonal holes are triangular holes.

8. The board as claimed in claim 1, wherein the linear slots are tapered in a direction perpendicular to the first side of the board and are arranged in multiple rows which intersect perpendicularly at even distance to each other on the first side, multiple square pyramids are formed between the linear slots and located as a matrix pattern.

9. The board as claimed in claim 8, wherein the geometric holes communicate with intersections of the linear slots.

10. The board as claimed in claim 9, wherein the geometric holes are polygonal-cone shaped holes.

11. The board as claimed in claim 10, wherein the geometric holes are triangular-cone shaped holes.

12. The board as claimed in claim 1, wherein a number of the geometric holes in the board is between 8000 to 450000 per meter square.

13. The board as claimed in claim 1, wherein a number of the geometric holes in the board is between 250000 to 400000 per meter square.

14. The board as claimed in claim 1, wherein an HBR of the board is between 10 to 90 and ductility of the board 1 is between 4 to 45.

15. The board as claimed in claim 1, wherein the board is made by metal.

16. The board as claimed in claim 1, wherein a minimum width of the geometric holes is smaller than a perpendicular distance between the first and second sides of the board.
